(19) United States
(12) Patent Application Publication
(10) Pub. No.: US 2007/0040567 A1
(43) Pub. Date: Feb. 22, 2007

(54) Method for test strip manufacturing and test card analysis

(76) Inventors: Natasha Popovich, Pompano Beach, FL (US); Brent E. Modzelewski, Boca Raton, FL (US); Dennis Slomski, Wellington, FL (US)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/504,710

(22) Filed: Aug. 16, 2006

Related U.S. Application Data
(60) Provisional application No. 60/708,366, filed on Aug. 16, 2005.

(51) Int. Cl. G01R 31/26

(52) U.S. Cl. 324/765

(57) ABSTRACT

A method of manufacturing a plurality of test strips is described where a web is formed containing conductive and base layers. A plurality of test strips are formed on the web by electrically isolating a first group of conductive components. Subsequently, a second group of conductive components are electrically isolated on the web by a different process. A test card for quality control analysis is also described, where the test card includes a plurality of attached test strip traces.

This application claims priority to U.S. Provisional Patent Application No. 60/708,366, filed Aug. 16, 2005, which is herein incorporated by reference.

### TECHNICAL FIELD

The present invention relates to electrochemical blood glucose sensors and, more particularly, to methods of sensor manufacture and quality control assessment.

### BACKGROUND

Many people require daily monitoring of their blood glucose levels. A number of systems that allow people to conveniently monitor their blood glucose levels are available. Such systems typically include a disposable test strip where the user applies a blood sample and a meter then determines the glucose level in the blood sample.

Among the various technologies available for measuring blood glucose levels, electrochemical technologies are particularly desirable because small volumes of blood sample can be used to perform the measurement. In electrochemical-based systems, the test strip typically includes a sample chamber that contains reagents, such as glucose oxidase and a mediator, and electrodes. When the user applies a blood sample to the sample chamber, the reagents react with the glucose. In amperometric electrochemical systems, the instrument applies a voltage to the electrodes to cause a redox reaction. The meter measures a current resulting from the reaction and calculates the glucose level based on the measured current.

It should be emphasized that accurate measurements of blood glucose levels can be critical to the long-term health of many users. As a result, there is a need for a high level of reliability, easy-of-use and allowance for poor user technique in the design of meters and test strips used to measure blood glucose levels. However, as sample sizes become smaller, the dimensions of the sample chamber and electrodes in the test strip also become smaller. This, in turn, can render the test systems more sensitive to manufacturing process and component variations, and to environmental factors such as user technique shortcomings, damage from handling, etc.

Accordingly, there is a need to provide low cost and high quality test strips employing high volume and efficient manufacturing processes. This includes the need for a test strip design that facilitates manufacturing with minimal production times to lower test strip cost, while maintaining high consistency and quality of test strip manufacture.

Several electrochemical sensor manufacturing methods have been proposed. One such method is described in U.S. Pat. No. 6,875,327 to Miyazaki et al. Miyazaki et al. describe a biosensor manufacturing process whereby a conductive layer is formed on a support. Electrodes are formed using a laser to form multiple “slits” in the conductive layer, electrically separating the working, counter and detecting electrodes. Following electrode formation, chemical reagents are selectively applied to the conductive layer. Spacer and cover layers are then applied to complete the biosensor.

Although the electrode design described by Miyazaki et al. can provide a functional biosensor, the design has not been optimized for manufacturability. Specifically, the electrodes are defined by unnecessary slits and some slits may be longer than required. The use of unnecessary and longer slits increases laser usage, manufacturing time and power consumption. Further, any deviations in the cutting process affecting the precision and/or accuracy of cuts defining electrode areas could introduce variances in the surface area, and hence the electrical properties, of the resulting biosensor. The imprecision and/or inaccuracy of electrode formation can impact the accuracy of tests performed using the test strips formed by the process proposed by Miyazaki et al.

The biosensor design and manufacturing method of the present invention addresses these and other problems in the prior art.

### SUMMARY OF THE INVENTION

The present invention includes methods for forming and testing electrochemical test strips having electrically isolated working electrodes using a test card. It is contemplated that a test card can include a plurality of conductive components for each test strip defined by a laser ablation process. The number of conductive of component can vary depending upon test strip design. Through advantageously utilizing a test strip design incorporating at least one electrically isolated component, quality control and manufacturing efficiency can be improved. Further, by minimizing the number and extent of vector formations during a laser ablation process, manufacturing time and concomitant cycle times of an ablation device can be reduced. These and other advantages can reduce the total manufacturing cost for electrochemical test strips.

One embodiment of the invention is directed to a method of manufacturing a plurality of test strips. The method includes forming a web containing a conductive layer and a base layer. The method also includes partially forming the plurality of test strips by electrically isolating a first group of conductive components in the conductive layer using a first process and

subsequently forming the plurality of test strips by electrically isolating a second group of conductive components in the conductive layer using a second process wherein first and second processes are not the same. Another embodiment of the invention is directed to a test card for quality control analysis. The test card may include a base layer, a conductive layer and a plurality of test strip traces.

Among other advantages realized by the present invention is reduced test strip handling. Quality control analysis can be conducted at any stage of the manufacturing process, and can evaluate the quality of any preceding manufacturing process or processes. Conducting quality control analysis on a test card containing a plurality of test strips can reduce manufacturing costs. In particular, manufacturing costs can be reduced by reducing the number of steps required to perform quality control analysis. For example, separation of a test card containing ten partially-formed or completed test strips from a web or reel of an array of test strips can be achieved with a single separation process, rather than ten separation processes. Further, the test card can be handled a single time, rather than ten separate handling processes required for ten separate test strips.

Quality control analysis performed according to illustrative embodiments of the present invention can be conducted using testing equipment designed to run a plurality of quality control tests in parallel. Parallel testing of multiple test strips on a single test card can reduce analysis time as compared to traditional methods of testing individual test strips.

Components on a test strip pattern intended to be electrically isolated can be tested for isolation during quality control analysis. For example the electrical isolation of working electrodes can be confirmed by testing the potential between the plurality of working electrodes and a single point of contact on the conductive layer. Traditional testing methods may require contact with a plurality of conductive elements, increasing the complexity of the testing device and time to perform the testing process.

Further advantages can be realized by placing quality control testing at any number of steps during the manufacturing process. By placing quality control analysis points immediately downstream of key manufacturing steps, losses can be minimized as manufacturing deviations can be quickly identified. The aim of quality control testing is to reduce time delays and inefficiencies in the manufacturing process and improve manufacturing output. Efficiencies can include reduced manufacturing time, reduced material usage, reduced energy consumption, reduced labor and other cost savings associated with optimal manufacturing processes.

Additional objects and advantages of the invention will be set forth in part in the description which follows, and in part will be obvious from the description, or may be learned by practice of the invention. The objects and advantages of the invention will be realized and attained by means of the elements and combinations particularly pointed out in the appended claims.

It is to be understood that both the foregoing general description and the following detailed description are exemplary and explanatory only and are not restrictive of the invention, as claimed.

### BRIEF DESCRIPTION OF THE DRAWINGS

The following drawings form part of the present specification and are included to further demonstrate certain aspects of the present invention. The invention may be better understood by reference to one or more of these drawings in combination with the detailed description of the specific embodiments presented herein:

FIG. 1 is a top plan view of a test strip according to an illustrative embodiment of the invention.

FIG. 2 is a cross-sectional view of the test strip of FIG. 1, taken along line 2-2.

FIG. 3 is a top view of a reel or web according to a further illustrative embodiment of the invention.

FIG. 4 is a top view of a test card according to a further illustrative embodiment of the invention.

FIG. 5 is a top view of a conductive layer according to an illustrative embodiment of the invention.

FIG. 6 is a top view of a dielectric layer according to an illustrative embodiment of the invention.

FIG. 7 is a diagram of the manufacturing process before production testing according to a further illustrative embodiment of the invention.

FIG. 8 is a diagram of the manufacturing process showing production testing according to a still further illustrative embodiment of the invention.

### DETAILED DESCRIPTION

In accordance with an illustrative embodiment, a design and manufacturing method for a test strip for measuring a fluid constituent is described. Many industries have a commercial need to monitor the concentration of particular constituents in a fluid. The oil refining industry, wineries, and the diary industry are examples of industries where fluid testing is routine. In the health care field, people such as diabetics, for example, have a need to monitor a particular constituent within their bodily fluids. A number of systems are available that allow people to test a body fluid, such as, blood, urine, or saliva, to conveniently monitor the level of a particular fluid constituent, such as, for example, cholesterol, proteins, and glucose.

The test strip includes a biosensor sample chamber or well for receiving the blood sample. The sample chamber can have a first opening in the proximal end of the test strip and a second opening for venting the sample chamber. The sample chamber can be dimensioned and arranged to draw and hold a blood sample into the sample chamber by capillary action. The test strip can further include a tapered or otherwise visually distinguishable section nearest the proximal end, in order to make it easier for the user to locate the first opening and supply a blood sample.

A working electrode, a counter electrode, a fill-detect electrode, and a fill-detect anode are disposed in the sample chamber. A reagent layer is disposed in the sample chamber and preferably covers at least the working electrode to form the biosensor. The reagent layer can include an enzyme, such as glucose oxidase, and a mediator, such as potassium ferricyanide or ruthenium hexamine. It is contemplated that other reagents and mediators can be used, and other analytes can be detected. The test strip can have, near its distal end, a plurality of electrical contacts that are electrically connected to the electrodes via conductive regions. The test strip can also include an auto-on conductor, which can be electrically isolated from the electrodes.

1. Test Strip Configuration

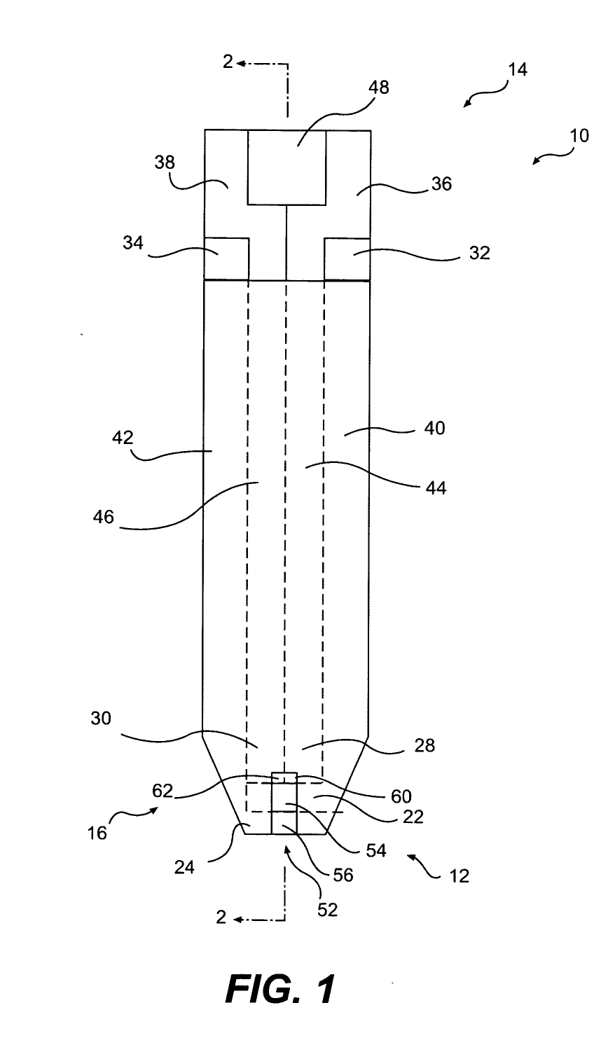

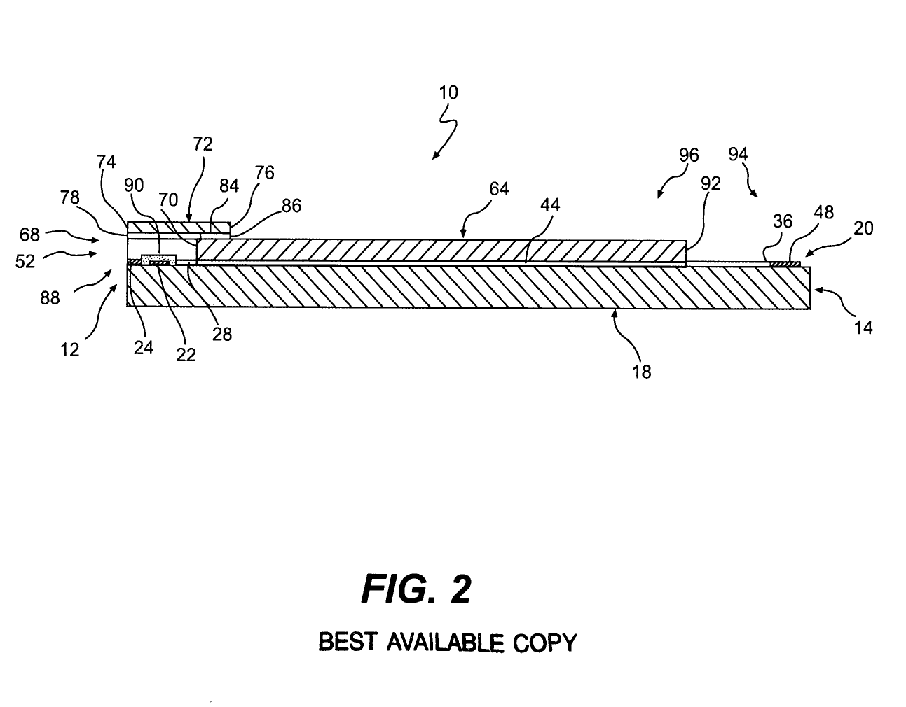

With reference to the drawings, FIGS. 1 and 2 show a test strip 10, in accordance with an exemplary embodiment of the present invention. Test strip 10 preferably takes the form of a generally flat strip that extends from a proximal end 12 to a distal end 14. Preferably, test strip 10 is sized for easy handling. For example, test strip 10 can measure approximately 35 mm long (i.e., from proximal end 12 to distal end 14) and approximately 9 mm wide. However, the strip can be any convenient length and width. For example, a meter with automated test strip handling may utilize a test strip smaller than 9 mm wide. Additionally, proximal end 12 can be narrower than distal end 14 in order to provide facile visual recognition of the distal end. Thus, test strip 10 can include a tapered section 16, in which the full width of test strip 10 tapers down to proximal end 12, making proximal end 12 narrower than distal end 14. As described in more detail below, the user applies the blood sample to an opening in proximal end 12 of test strip 10. Thus, providing tapered section 16 in test strip 10, and making proximal end 12 narrower than distal end 14, assists the user in locating the opening where the blood sample is to be applied. Further, other visual means, such as indicia, notches, contours or the like are possible.

As shown in FIG. 2, test strip 10 can have a generally layered construction. Working upwardly from the bottom layer, test strip 10 can include a base layer 18 extending along the entire length of test strip 10. Base layer 18 can be formed from an electrically insulating material and has a thickness sufficient to provide structural support to test strip 10. For example, base layer 18 can be a polyester material about 0.35 mm thick.

According to the illustrative embodiment, a conductive layer 20 is disposed on base layer 18. Conductive layer 20 includes a plurality of electrodes disposed on base layer 18 near proximal end 12, a plurality of electrical contacts disposed on base layer 18 near distal end 14, and a plurality of conductive regions electrically connecting the electrodes to the electrical contacts. In the illustrative embodiment, the plurality of electrodes includes a working electrode 22, a counter electrode 24, a fill-detect anode 28, and a fill-detect cathode 30. Correspondingly, the electrical contacts can include a working electrode contact 32, a counter electrode contact 34, a fill-detect anode contact 36, and a fill-detect cathode contact 38. The conductive regions can include a working electrode conductive region 40, electrically connecting working electrode 22 to working electrode contact 32, a counter electrode conductive region 42, electrically connecting counter electrode 24 to counter electrode contact 34, a fill-detect anode conductive region 44 electrically connecting fill-detect anode 28 to fill-detect contact 36, and a fill-detect cathode conductive region 46 electrically connecting fill-detect cathode 30 to fill-detect cathode contact 38. Further, the illustrative embodiment is depicted with conductive layer 20 including an auto-on conductor 48 disposed on base layer 18 near distal end 14.

The next layer in the illustrative test strip 10 is a dielectric spacer layer 64 disposed on conductive layer 20. Dielectric spacer layer 64 is composed of an electrically insulating material, such as polyester. Dielectric spacer layer 64 can be about 0.127 mm thick and cover portions of working electrode 22, counter electrode 24, fill-detect anode 28, fill-detect cathode 30, and conductive regions 40-46, but in the illustrative embodiment does not cover electrical contacts 32-38 or auto-on conductor 48. For example, dielectric spacer layer 64 can cover substantially all of conductive layer 20 thereon, from a line just proximal of contacts 32 and 34 all the way to proximal end 12, except for a slot 52 extending from proximal end 12. In this way, slot 52 can define an exposed portion 54 of working electrode 22, an exposed portion 56 of counter electrode 24, an exposed portion 60 of fill-detect anode 28, and an exposed portion 62 of fill-detect cathode 30.

A cover 72, having a proximal end 74 and a distal end 76, can be attached to dielectric spacer layer 64 via an adhesive layer 78. Cover 72 can be composed of an electrically insulating material, such as polyester, and can have a thickness of about 0.1 mm. Additionally, the cover 72 can be transparent.

Adhesive layer 78 can include a polyacrylic or other adhesive and have a thickness of about 0.013 mm. Adhesive layer 78 can consist of sections disposed on spacer 64 on opposite sides of slot 52. A break 84 in adhesive layer 78 extends from distal end 70 of slot 52 to an opening 86. Cover 72 can be disposed on adhesive layer 78 such that its proximal end 74 is aligned with proximal end 12 and its distal end 76 is aligned with opening 86. In this way, cover 72 covers slot 52 and break 84.

Slot 52, together with base layer 18 and cover 72, defines a sample chamber 88 in test strip 10 for receiving a blood sample for measurement in the illustrative embodiment. Proximal end 12 of slot 52 defines a first opening in sample chamber 88, through which the blood sample is introduced into sample chamber 88. At distal end 70 of slot 52, break 84 defines a second opening in sample chamber 88, for venting sample chamber 88 as sample enters sample chamber 88. Slot 52 is dimensioned such that a blood sample applied to its proximal end 68 is drawn into and held in sample chamber 88 by capillary action, with break 84 venting sample chamber 88 through opening 86, as the blood sample enters. Moreover, slot 52 can advantageously be dimensioned so that the blood sample that enters sample chamber 88 by capillary action is about 1 micro-liter or less. For example, slot 52 can have a length (i.e., from proximal end 12 to distal end 70) of about 0.140 inches, a width of about 0.060 inches, and a height (which can be substantially defined by the thickness of dielectric spacer layer 64) of about 0.005 inches. Other dimensions could be used, however.

A reagent layer 90 is disposed in sample chamber 88. In the illustrative embodiment, reagent layer 90 covers at least exposed portion 54 of working electrode 22. Further according to the illustrative embodiment, reagent layer 90 also at least contacts exposed portion 56 of counter electrode 24. Reagent layer 90 includes chemical constituents to enable the level of glucose or other analyte in the test fluid, such as a blood sample, to be determined electrochemically. Thus, reagent layer 90 can include an enzyme specific for glucose, such as glucose oxidase, and a mediator, such as potassium ferricyanide or ruthenium hexamine. Reagent layer 90 can also include other components, such as buffering materials (e.g., potassium phosphate), polymeric binders (e.g., hydroxypropyl-methyl-cellulose, sodium alginate, microcrystalline cellulose, polyethylene oxide, hydroxyethylcellulose, and/or polyvinyl alcohol), and surfactants (e.g., Triton X-100 or Surfynol 485).

With these chemical constituents, reagent layer 90 reacts with glucose in the blood sample in the following way. The glucose oxidase initiates a reaction that oxidizes the glucose to gluconic acid and reduces the ferricyanide to ferrocyanide. When an appropriate voltage is applied to working electrode 22, relative to counter electrode 24, the ferrocyanide is oxidized to ferricyanide, thereby generating a current that is related to the glucose concentration in the blood sample.

As depicted in FIG. 2, the arrangement of the various layers in illustrative test strip 10 can result in test strip 10 having different thicknesses in different sections. In particular, among the layers above base layer 18, much of the thickness of test strip 10 can come from the thickness of spacer 64. Thus, the edge of spacer 64 that is closest to distal end 14 can define a shoulder 92 in test strip 10. Shoulder 92 can define a thin section 94 of test strip 10, extending between shoulder 92 and distal end 14, and a thick section 96, extending between shoulder 92 and proximal end 12. The elements of test strip 10 used to electrically connect it to the meter, namely, electrical contacts 32-38 and auto-on conductor 48, can all be located in thin section 94. Accordingly, the connector in the meter can be sized and configured to receive thin section 94 but not thick section 96, as described in more detail below. This can beneficially cue the user to insert the correct end, i.e., distal end 14 in thin section 94, and can prevent the user from inserting the wrong end, i.e., proximal end 12 in thick section 96, into the meter.

Although FIGS. 1 and 2 illustrate an illustrative embodiment of test strip 10, other configurations, chemical compositions and electrode arrangements could be used.

Different arrangements of fill-detect electrodes 28 and 30 can also be used. In the configuration shown in FIGS. 1 and 2, fill-detect electrodes 28 and 30 are in a side-by-side arrangement. Alternatively, fill-detect electrodes 28 and 30 can be in a sequential arrangement, whereby, as the sample flows through sample chamber 88 toward distal end 70, the sample contacts one of the fill-detect electrodes first (either the anode or the cathode) and then contacts the other fill-detect electrode.

As depicted in the Figures, fill-detect electrodes 28 and 30 are advantageously located on the distal side of reagent layer 90. In this arrangement, the sample introduced into the sample chamber 88 will have traversed reagent layer 90 before reaching fill-detect electrodes 28 and 30. This arrangement beneficially allows the fill-detect electrodes 28 and 30 to indicate not only whether sufficient blood sample is present in sample chamber 88, but also when, concomitantly, the blood sample has sufficiently mixed with the chemical constituents of reagent layer 90. Other configurations are of course possible.

2. Test Strip Array Configuration

Test strips can be manufactured by forming a plurality of strips in an array along a reel or web of substrate material. The term “reel” or “web” as used herein applies to continuous webs of indeterminate length, or to sheets of determinate length. The individual strips, after being formed, can be separated during later stages of manufacturing. An illustrative embodiment of a batch process of this type is described infra. First, an illustrative test strip array configuration is described.

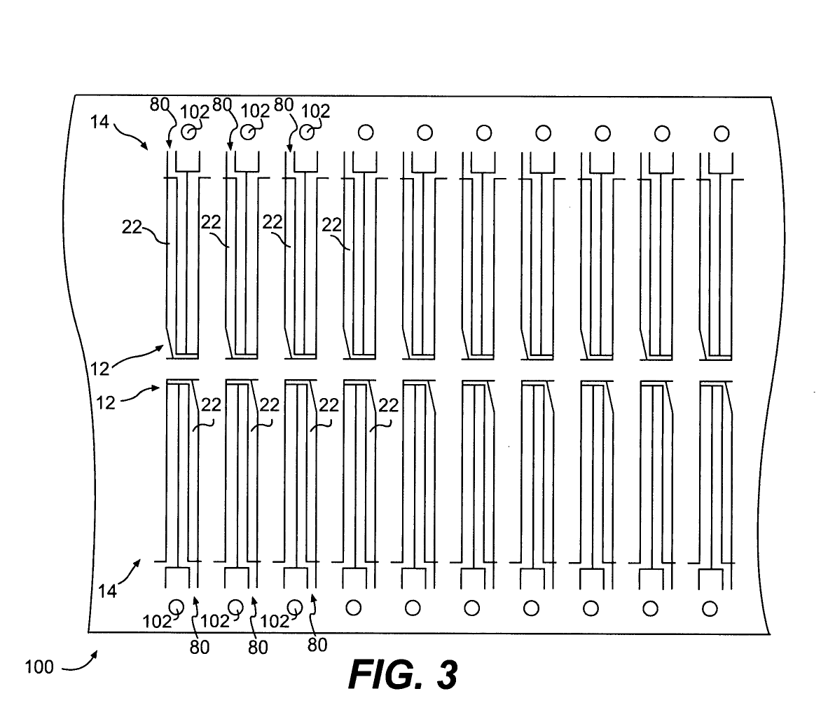

FIG. 3 shows a series of traces 80 formed in a substrate material coated with a conductive layer. Traces 80, formed in the exemplary embodiment by laser ablation, partially form the conductive layers of two rows of ten test strips as shown. In the exemplary embodiment depicted, proximal ends 12 of the two rows of test strips are in juxtaposition in the center of a reel 100. The distal ends 14 of the test strips are arranged at the periphery of reel 100. It is also contemplated that the proximal ends 12 and distal ends 14 of the test strips can be arranged in the center of reel 100. Alternatively, the two distal ends 14 of the test strips can be arranged in the center of reel 100. The lateral spacing of the test strips is designed to allow a single cut to separate two adjacent test strips. The separation of the test strip from reel 100 can electrically isolate one or more conductive components of the separated test strip 10.

As depicted in FIG. 3, trace 80 for an individual test strip forms a plurality of conductive components; e.g., electrodes, conduction regions and electrode contacts. Trace 80 is comprised of individual cuts made by a laser following a specific trajectory, or vector. A vector can be linear or curvilinear, and define spaces between conductive components that are electrically isolating. Generally a vector is a continuous cut made by the laser beam.

The conductive components can be partially or entirely defined by ablated regions, or laser vectors, formed in the conductive layer. The vectors may only partially electrically isolate the conductive component, as the component can remain electrically connected to other components following laser ablation. The electrical isolation of the conductive components can be achieved following “singulation,” when individual test strips are separated from reel or web 100.

FIG. 3 shows a plurality of electrically isolated working electrodes 22. According to the illustrated embodiment, working electrode 22 of an individual test strip can be electrically isolated from the other conductive components during the laser ablation process. It is also contemplated that other conductive components may be electrically isolated during the laser ablation process. For example, fill detect electrodes may be isolated with the addition of one or more vectors.

FIG. 3 also includes registration points 102 at the distal end 14 of each test strip on reel 100. Registration points 102 assist the alignment of the layers during the lamination, punching and other manufacturing processes. It is further contemplated that registration points 102 may be located at locations other than the distal end 14 of each test strip trace 80 on reel 100. High quality manufacturing may require additional registration points 102 to ensure adequate alignment of laminate layers and/or other manufacturing processes, such as, for example, laser ablation of conductive components, reagent deposition, singulation, etc.

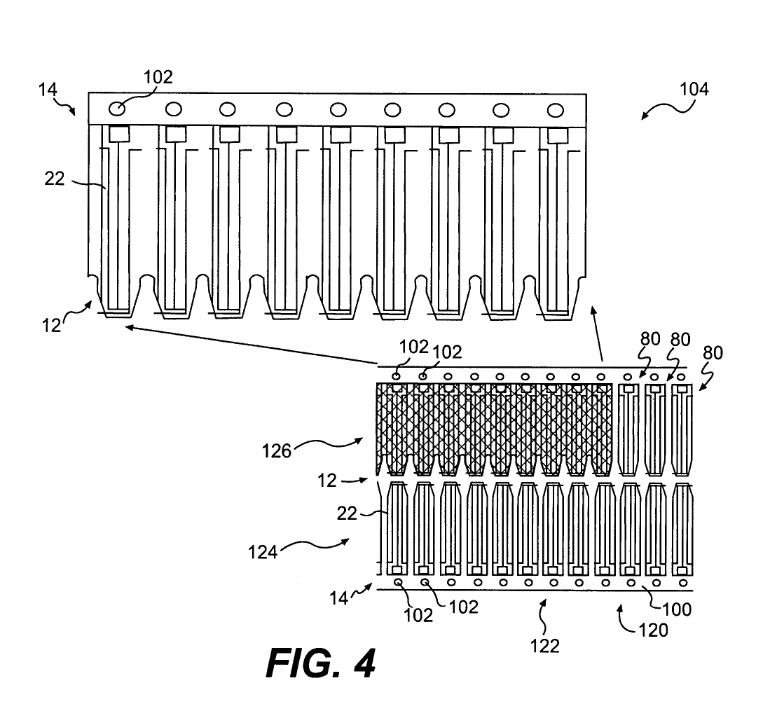

FIG. 4 shows a “test card” 104 separated from reel 100. Test card 104 can contain a plurality of test strips 10 or traces 80, and a plurality of conductive components. In the preferred embodiment test card 104 can contain between 6 and 12 test strips 10 or traces 80. In other embodiments, test card 104 can contain a plurality of test strips 10 or traces 80. In the illustrated embodiment, test card 104 can include a lateral array of test strips 10 or traces 80. In other embodiments, test card 104 can include an array or arrays of test strips 10 or traces 80 in longitudinal and/or lateral configurations. It is further contemplated that test strips 10 or traces 80 may be in any arrangement on reel 100 suitable for manufacturing.

Test card 104 contains a plurality of conductive components. Some conductive components can be electrically isolated when the test card is removed from the reel. As shown in FIG. 4, working electrode 22 is electrically isolated. Other embodiments could include additional electrically isolated conductive components not shown in FIG. 4. It may be possible to analyze properties of the electrically isolated conductive components to assess the quality of the manufacturing process. The efficiency of the quality assessment process can be increased by testing at least one of the plurality of electrically isolated conductive components.

3. Batch Manufacturing of Test Strips

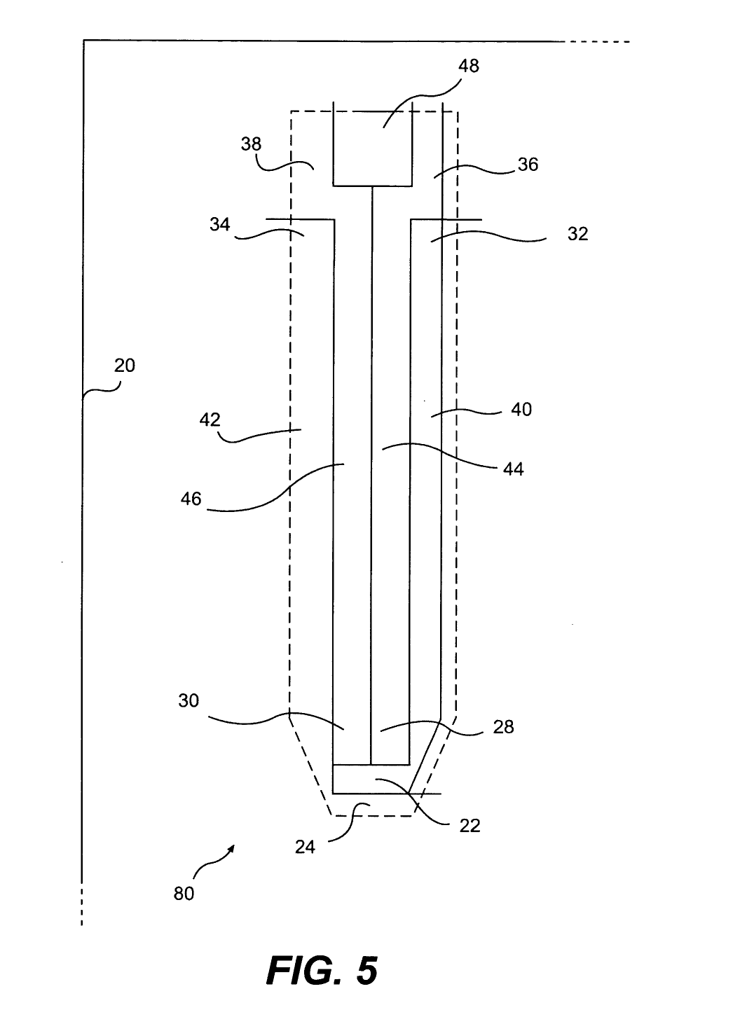

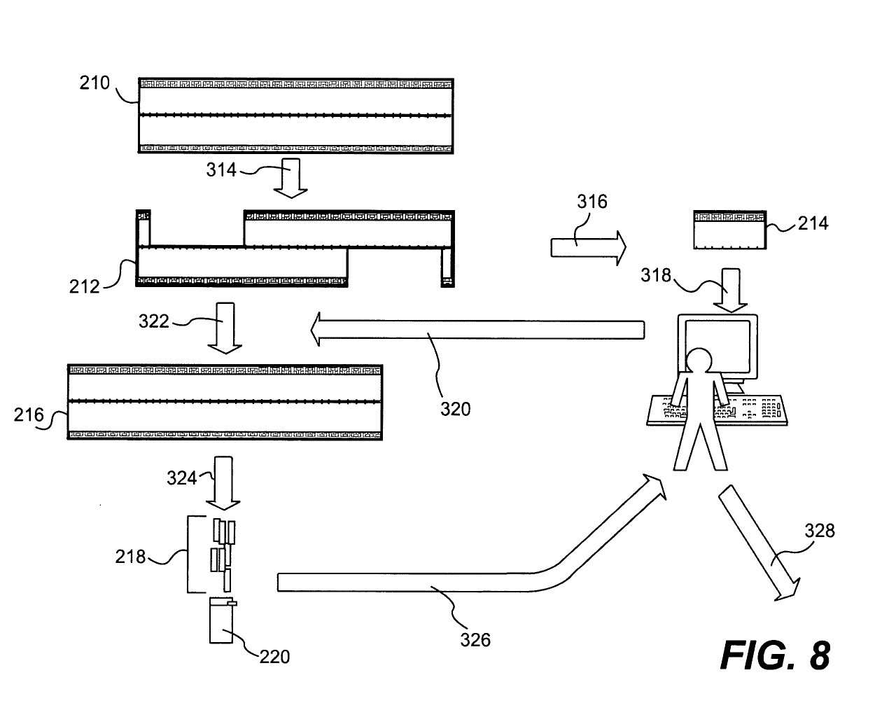

FIGS. 5 through 8 illustrate an exemplary method of manufacturing test strips. Although these figures shows steps for manufacturing test strip 10, as shown in FIGS. 1 and 2, it is to be understood that similar steps can be used to manufacture test strips having other configurations.

With reference to FIG. 4, a plurality of test strips 10 can be produced by forming a structure 120 that includes a plurality of test strip traces 122 on reel 100. Test strip traces 122 include a plurality of traces 80, and can be arranged in an array that includes a plurality of rows. Each row 124 can include a plurality of test strip traces 122.

The separation process can also be used to electrically isolate conductive components of test strip 10. Laser ablation of the conductive layer may not electrically isolate certain conductive components. The non-isolated conductive components may be isolated by the separation process whereby test strips are separated from reel 100. The separation process may sever the electrical connection, isolated the conductive component. Separating test strip 10 can electrically isolate the counting electrode 24, fill detect-anode 28 and fill-detect cathode 30. The separation process can complete the electrical isolation of conductive components by selectively separating conductive components.

Further, the separation process can provide some or all of the shape of the perimeter of the test strips 10. For example, the tapered shape of tapered sections 16 of the test strips 10 can be formed during this punching process. Next, a slitting process can be used to separate the test strip structures 122 in each row 124 into individual test strips 10. The separation process may include stamping, slitting, scoring and breaking, or any suitable method to separate test strip 10 and/or test card 104 from reel 100.

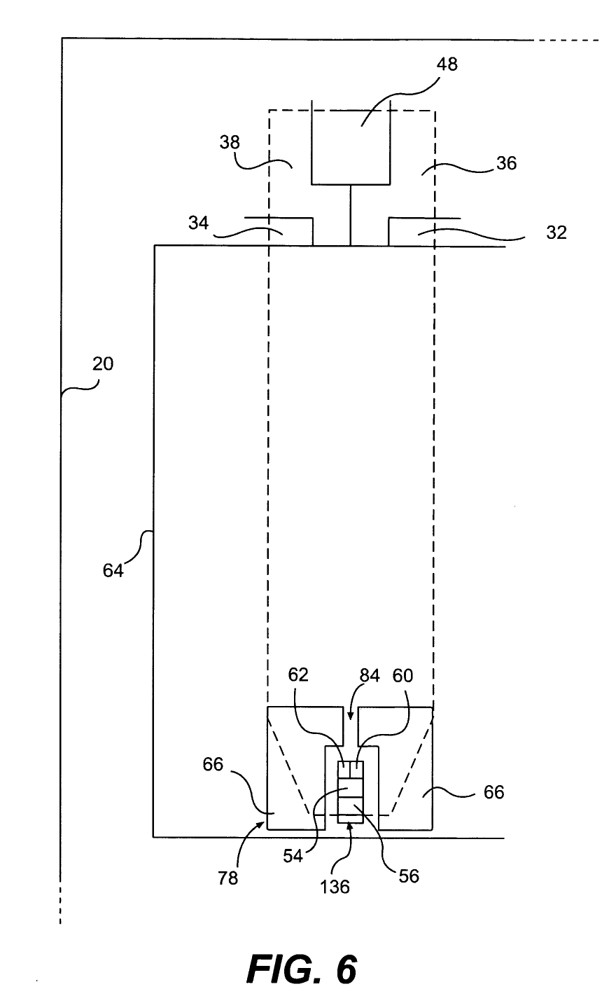

FIGS. 5 and 6 show only one test strip structure (either partially or completely fabricated), in order to illustrate various steps in a preferred method for forming the test strip structures 122. In this exemplary approach, the test strip structures 122 in integrated structure 120 are all formed on a sheet of material that serves as base layer 18 in the finished test strips 10. The other components in the finished test strips 10 are then built up layer-by-layer on top of base layer 18 to form the test strip structures 122. In each of FIGS. 5 and 6, the outer shape of the test strip 10 that would be formed in the overall manufacturing process is shown as a dotted line.

The exemplary manufacturing process employs base layer 18 covered by conductive layer 20. Conductive layer 20 and base layer 18 can be in the form of a reel, ribbon, continuous web, sheet, or other similar structure. Conductive layer 20 can include any suitable conductive or semi-conductor material, such as gold, silver, palladium, carbon, tin oxide and others known in the art. Conductive layer 20 can be formed by sputtering, vapor deposition, screen printing or any suitable manufacturing method. The conductive material can be any suitable thickness and can be bonded to base layer 18 by any suitable means.

As shown in FIG. 5, conductive layer 20 can include working electrode 22, counter electrode 24, fill-detect anode 28, and fill-detect cathode 30. Trace 80 can be formed by laser ablation where laser ablation can include any device suitable for removal of the conductive layer in appropriate time and with appropriate precision and accuracy. Various types of lasers can be used for sensor fabrication, such as, for example, solid-state lasers (e.g. Nd:YAG and titanium sapphire), copper vapor lasers, diode lasers, carbon dioxide lasers and excimer lasers. Such lasers may be capable of generating a variety of wavelengths in the ultraviolet, visible and infrared regions. For example, excimer laser provides wavelength of 248 nm, a fundamental Nd:YAG laser gives 1064 nm, a frequency tripled Nd:YAG wavelength is at 355 nm and a Ti:sapphire laser is at approximately 800 nm. The power output of these lasers may vary and is usually in range 10-100 watts.

The laser ablation process can include a laser system. The laser system can include a laser source. The laser system can further include means to define trace 80, such as, for example, a focused beam, projected mask or other suitable technique. The use of a focused laser beam can include a device capable of rapid and accurate controlled movement to move the focused laser beam relative to conductive layer 20. The use of a mask can involve a laser beam passing through the mask to selectively ablate specific regions of conductive layer 20. A single mask can define test strip trace 80, or multiple masks may be required to form test strip trace 80. To form trace 80, the laser system can move relative to conductive layer 20. Specifically, the laser system, conductive layer 20, or both the laser system and conductive layer 20 may move to allow formation trace 80 by laser ablation. Exemplary devices available for such ablation techniques include Microline Laser system available from LPKF Laser Electronic GmbH (Garbsen, Germany) and laser micro machining systems from Exitech, Ltd (Oxford, United Kingdom).

In the next step, dielectric spacer layer 64 can be applied to conductive layer 20, as illustrated in FIG. 6. Spacer 64 can be applied to conductive layer 20 in a number of different ways. In an exemplary approach, spacer 64 is provided as a sheet or web large enough and appropriately shaped to cover multiple test strip traces 80. In this approach, the underside of spacer 64 can be coated with an adhesive to facilitate attachment to conductive layer 20. Portions of the upper surface of spacer 64 can also be coated with an adhesive in order to provide adhesive layer 78 in each of the test strips 10. Various slots can be cut, formed or punched out of spacer 64 to shape it before, during or after the application of spacer layer 64 to conductive layer 20. For example, as shown in FIG. 6, spacer 64 can have a pre-formed slot 136 for each test strip structure. In addition, spacer 64 can include adhesive sections 66, with break 84 there between, for each test strip trace 80. Spacer 64 is then positioned over conductive layer 20, as shown in FIG. 6, and laminated to conductive layer 20. When spacer 64 is appropriately positioned on conductive layer 20, exposed electrode portions 54-62 are accessible through slot 136. Thus, slot 52 in test strip 10 corresponds to that part of slot 136 that remains in test strip 10 after the test strip structures are separated into test strips. Similarly, spacer 64 leaves contacts 32-38 and auto-on conductor 48 exposed after lamination. In some embodiments, spacer 64 may include a heat sealable layer as described in commonly-assigned, copending provisional U.S. patent application “Biosensors Comprising Heat Sealable Spacer Materials”, filed Apr. 18, 2006 (Attorney Docket 06882-6014), the disclosure of which is hereby incorporated herein by reference in its entirety. Such a heat sealable spacer may more accurately define one or more edges of electrodes, electrical contacts, and/or conductive regions.

Alternatively, spacer 64 could be applied in other ways. For example, spacer 64 can be injection molded onto base layer 18 and dielectric 50. Spacer 64 could also be built up on dielectric layer 50 by screen-printing successive layers of a dielectric material to an appropriate thickness, e.g., about 0.005 inches. A preferred dielectric material comprises a mixture of silicone and acrylic compounds, such as the “Membrane Switch Composition 5018” available from E.I. DuPont de Nemours & Co., Wilmington, Del. Other materials could be used, however.

Reagent layer 90 can then be applied to each test strip structure. In an illustrative approach, reagent layer 90 is applied by dispensing an aqueous composition onto exposed portion 54 of working electrode 22 and letting it dry to form reagent layer 90. An exemplary aqueous composition has a pH of about 7.5 and contains 175 mM ruthenium hexamine, 75 mM potassium phosphate, 0.35% METHOCEL water-soluble cellulose ether, 0.08% TRITON X-100 nonionic surfactant, 5000 u/mL glucose dehydrogenase, 5% sucrose, and 0.05% SILWET L-7608 silicone surfactant. Alternatively, other methods, such as screen-printing, spray deposition, piezo and ink jet printing, can be used to apply the composition used to form reagent layer 90.

A transparent cover 72 can then be attached to adhesive layer 78. Cover 72 may be large enough to cover multiple test strip structures 122. Attaching cover 72 can complete the formation of the plurality of test strip structures 122. The plurality of test strip structures 122 can then be separated from each other to form a plurality of test strips 10, as described above.

4. Quality Control Testing of Test Strips

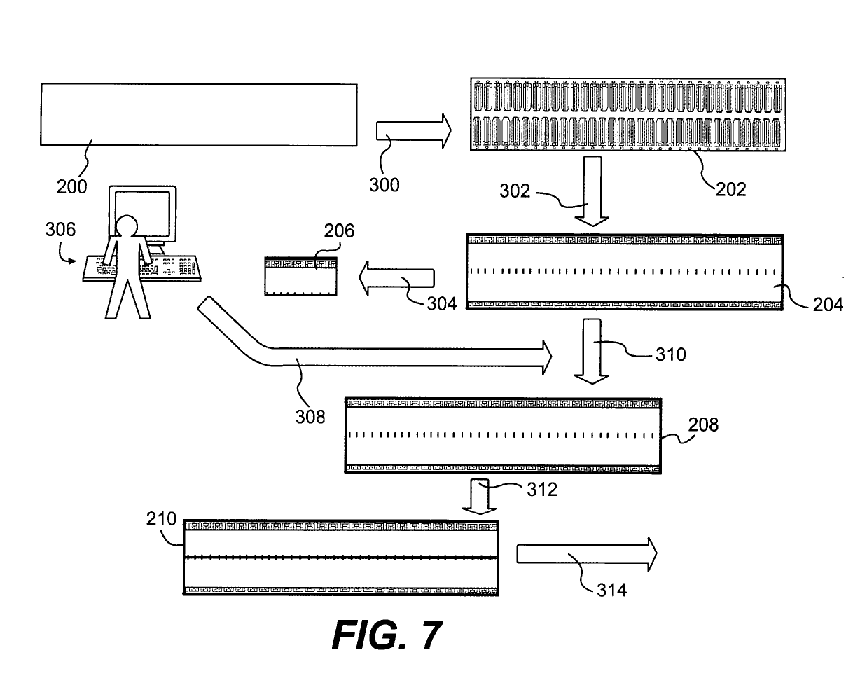

FIG. 7 shows a further illustrative embodiment of a test strip manufacturing method. The manufacturing method utilizes a web 200 containing conductive layer 20 and base layer 18. Conductive layer 20 and base layer 18 can be any suitable material. Web 200 can be any dimension suitable for production of the test strips. Web 200 is passed through any suitable device and ablated by process 300.

Ablation 300 can include any suitable ablation process capable of forming conductive components in conductive layer 20. In the illustrative embodiment, ablation 300 is achieved by laser ablation. The ablation process may not electrically isolate all conductive components. For example, counter electrode 24 may not be isolated by laser ablation but can be isolated by subsequent separation from web 200. In the illustrative embodiment, working electrode 22 is electrically isolated during ablation process 300. The counter electrode 24, fill-detect anode 28 and fill-detect cathode 30 may not be electrically isolated during ablation process 300. Specifically, subsequent separation process can electrically isolate the counter electrode 24, fill-detect anode 28 and fill-detect cathode 30.

Web 200 can be passed through any suitable ablation device at speeds sufficient to produce an appropriate rate of test strip production. The ablation process can be sufficiently rapid to allow the continuous movement of web 200 through the laser ablation device. Alternatively, web 200 can be passed through the ablation device in a non-continuous (i.e., start-and-stop) manner.

The properties of the conductive components formed by ablation process 300 can be analyzed during or following ablation process 300. Analysis of ablation process 300 can include optical, chemical, electrical or any other suitable analysis means. The analysis can monitor the entire ablation process, or part of the ablation process. For example, the analysis can include monitoring vector formation to ensure the dimensions of the formed vector are within predetermined tolerance ranges.

Quality control analysis can also include monitoring the effectiveness and/or efficiency of the vector formation process. In particular, the width of the resulting vectors can be monitored to ensure acceptable accuracy and precision of the cuts in conductive layer 20. For example, the quality of the laser ablation process can be analyzed by monitoring the surface of conductive layer 20 and/or base layer 18 following ablation. Partial ablation of base layer 18 can indicate that the laser power is set too high or the beam is traveling too slowly. By contrast, a partially ablated conductive layer may indicate insufficient laser power or that the beam is traveling too quickly. Incomplete ablation of gaps may result in the formation of vectors that are not electrically isolating between conductive components.

In the illustrative embodiment, the dimensions of working electrode 22 can be analyzed to determine the quality of the manufacturing process. For example optical analysis (not shown) can monitor the width of working electrode 22 to ensure sufficient accuracy of ablation process 300. Further, the alignment of working electrode 22 relative to registration points 102 can be monitored. Optical analysis can be performed by using VisionPro system from Cognex Vision Systems (Natick, Mass.).

As described above, the ablation process produces an array of test strips 202 on web 200. Following formation of test strip array 202 and corresponding conductive components, dielectric spacer 64 is laminated to conductive layer 20. The spacer lamination process 302 can include registration points 102 to correctly align spacer layer 64 with conductive layer 20. Spacer 64 may contain registration points 102 corresponding to registration points 102 of test strip array 202. The correct alignment of the layers will position slot 136 over the electrodes as indicated in FIG. 6, forming a three-layer laminate 204. Following the formation of three-layer laminate 204, a test card 206 can be separated from three-layer laminate 204 by any suitable test card separation process 304.

Test card 206 can be analyzed by test card analysis process 306 to test the quality of any previous manufacturing process. Analysis 306 of test card 206 can include optical, electrical, chemical or any other suitable means for testing test card 206. In an illustrative embodiment, the electrical properties of working electrode 22 can be tested. At least one of the plurality of working electrodes 22 of test card 206 can be analyzed for electrochemical and surface properties. For example, chronoamperometry can be used to test working electrode 22. Chronoamperometry is an electrochemical technique that uses a voltage signal for excitation and measures current generated as a result of the excitation as a function of time.

The results of analysis 306 can be compared to previous manufacturing process. Alternatively, the results of analysis 306 may be compared to modeled or simulated results using computational methods. The results can be used to ensure high-quality manufacturing processes. Deviation from acceptable or expected results may require altering upstream manufacturing processes, or altering downstream manufacturing processes to address the deviations. Following acceptance of the results of analysis 306, the quality of upstream manufacturing processes can be confirmed.

Following satisfactory feedback 308 from test card analysis 306, the chemistry can be applied to three-layer laminate 204 by a chemistry application process 310. The resulting laminate 208 can contain any appropriate reagent suitable for the specific test strip. The reagent application process 310 can include any appropriate process. In the preferred embodiment, quality control testing is not performed following reagent application 310. In other embodiments, quality control testing can be conducted following chemistry application 310. For example, quality control analysis can monitor the effectiveness of the chemistry application. Specifically, optical analysis may be required to determine the extent of reagent covering working electrode 22 and/or counter electrode 24. Alternatively, any previous or upstream manufacturing process can be tested following formation of laminate 208.

Following reagent application 310, cover 72 can be applied to laminate 208 using any appropriate cover application process 312. Cover 72 may be centered on laminate 208. The resulting laminate 210 can be tested to ensure the quality of the cover application process 312. For example, optical means can be used to monitor the alignment of the cover to laminate 208. Alternatively, laminate 210 can be tested to ensure the quality of any upstream manufacturing process as described previously. Following cover application 312, laminate 210 can be moved to production testing 314.

The manufacturing process can be halted at any stage based upon the results of the quality control testing during manufacturing or production. Alternatively, one or more manufacturing processes can be adjusted based on the results of the quality control analysis. Quality control tests can be conducted in real time, and/or may include analysis of test cards removed from the production line. If the quality control testing is performed on test cards taken out of the production line, any production of the same lot or batch can be intercepted in the manufacturing process downstream of the quality control testing. Test card 206 can contain addressable information, identifying where the test card was removed from the production line. Consequently any deviations from appropriate manufacturing quality can be isolated to specific regions of the production line.

5. Test Strip Characterization

Laminate 210 moves to production following formation. Production can include a sampling plan to determine the frequency and location within the assembled web 212 of test card 214 separation by test card separation process 316. Test cards 214 can be subjected to preliminary strip characterization 318. Preliminary strip characterization 318 can include testing test card 214 to analyze any previous manufacturing process. The testing can include assigning each test card 214 a predetermined code number.

Following preliminary test strip characterization 318, test strips of the assembled web 212 can be printed with coded numbers 322 to form a coded assembled web 216. The coded numbers can be defined by the preliminary test strip characterization 318 performed on test card 214. The corresponding section within the production line may be assigned the same coded numbers as the extracted test card 214. The coded number may be any suitable identifier containing batch, lot, manufacturing, and/or other information pertinent to the manufacturing process, test strip 10, and/or meter. It is further contemplated that test card 206 and/or test card 214 can contain addressable information identifying where the test card was removed from the production line. In particular, the addressable information may allow the application of different coded numbers to different regions of assembled web 212. Consequently, coded assembled web 216 may contain different coded numbers 322 as defined by the preliminary test strip characterization 318. Further, the addressable information may allow any deviations from appropriate manufacturing quality to be isolated to specific regions of the production line. Tracking the quality of manufacturing processes can reduce production downtime and improve manufacturing efficiency.

In some embodiments, test strip 10 and/or test card 214 may be encoded with one or more conductive patterns, wherein each conductive pattern may encode any suitable information. Such a coding system is described in commonly-assigned, copending non-provisional U.S. patent application Ser. No. 11/181,778 “Diagnostic Strip Coding System and Related Methods of Use”, filed Jul. 15, 2005, the disclosure of which is hereby incorporated herein by reference in its entirety. A conductive pattern may include regions of conductive and non-conductive material representing an embedded code. The conductive pattern may contain calibration and other information related to the manufacture and/or use of test strip 10. Such information may be used to confirm proper calibration and/or operation of test strip 10.

Extracted test card 214 can be analyzed by preliminary test strip characterization 318. Preliminary test strip characterization 318 can include analysis of multiple test strips 10 within extracted test card 214. Analysis of multiple test strips 10 can be used to generate statistics for the variation of characteristics of test strips 10 within extracted test card 214. The statistics may be used to generate data related to the variation of test strips 10 within extracted test card 214. The data may be used to establish an upper bound for the variability of test strips within extracted test card 214. For example, variation among test strips 10 above a specified level may required the application of different coded numbers to form coded assembled web 216. The variation may also be used to increase the frequency of extracted test card 214 sampling to ensure suitable manufacturing quality control.

Coded assembled web 216 containing test strips 10 with coded numbers can be passed into a device to form singulated test strips 218. The singulation process 324 can include singulation of the individual test strips and/or any appropriate handling or packaging process. Singulated test strips 218 can be further processed if required. For example, test strips 10 of the coded assembled web 216 can be singulated and placed in storage vials 220. Alternatively, if the test strip sensor and/or associated meter does not require singulated test strips 218, the singulation process 324 can be substituted with an appropriate separation of coded assembled web 216 to form any required test strip array (e.g., wheel of strips, linear sub-array, etc.)

Singulated test strips 218 can be analyzed 326 for final verification, precision and/or glucose control testing. It is also contemplated that singulated test strips 218 can be analyzed 326 to verify printed codes. For example, singulated test strips 218 can contain different coded numbers if different regions of assembly web 212 show different preliminary test strip characterization 318. Following satisfactory results from the quality control analysis, test strips 218 can be sent to packaging or any other appropriate manufacturing process 328.

It is contemplated that test strips employing alternative trace designs could be produced using the manufacturing process described herein. For example, arranging two proximal ends 12 of test strips 10 in the center of reel 100 allows the application of a single cover 72. Arranging two distal ends 14 of test strips 10 in the center of reel 100, or proximal ends 12 and distal ends 14, may require the application of two separate covers 72. Further, test strips 10 of the current invention are aligned to reduce the number of cuts required to singulate test strips 10. The reduced number of cutting steps may reduce wear on the cutting tool, material waste and processing time.

6. Conclusion

Preferred embodiments of the present invention have been described above. Those skilled in the art will understand, however, that changes and modifications may be made to these embodiments without departing from the true scope and spirit of the invention, which is defined by the claims.

What is claimed is:

1. A method of manufacturing a plurality of test strips, comprising:
forming a web containing a conductive layer and a base layer;
partially forming said plurality of test strips by electrically isolating a first group of conductive components in the conductive layer using a first process; and
subsequently forming said plurality of test strips by electrically isolating a second group of conductive components in the conductive layer using a second process wherein first and second processes are not the same.

2. The method of claim 1, wherein the web includes a plurality of registration points.

3. The method of claim 1, wherein the first process includes a laser ablation process.

4. The method of claim 1, wherein the second process includes a separation process.

5. The method of claim 4, wherein the separation process includes stamping.

6. The method of claim 4, wherein the separation process includes separating a plurality of test strips from the web.

7. The method of claim 2, wherein the plurality of registration points are separated by approximately 9 mm.

8. The method of claim 2, wherein the plurality of registration points are separated by less than approximately 9 mm.

9. The method of claim 1, wherein the first group of conductive components are separated by less than approximately 9 mm.

10. The method of claim 4, wherein a plurality of test strips are separated by a single separation process to form a test card.

11. The method of claim 10, wherein the test card includes 6 to 12 test strips.

12. The method of claim 1, wherein the method further includes analyzing the formation of the conductive components.

13. The method of claim 12, wherein analyzing the formation of the conductive components includes optical analysis.

14. The method of claim 12, wherein at least one of the plurality of test strips is analyzed to determine one or more properties of the electrically isolated conductive components.

15. The method of claim 14, wherein the working electrode of the at least one of the plurality of test strips is analyzed by chronoamperometry.

16. A method of analyzing the manufacture of a plurality of test strips, comprising:
forming a web containing a plurality of test strips;
defining an addressable location within the web for at least one of the plurality of test strips; and
analyzing the at least one of the plurality of test strips.

17. The method of claim 16, wherein the method further includes encoding the at least one of the plurality of test strips with an identifier.

18. The method of claim 17, wherein the method further includes verification of the encoding of the at least one of the plurality of test strips.

19. A test card for quality control analysis, comprising:
a base layer;
a conductive layer; and
a plurality of test strip traces.

20. The test card of claim 19, wherein the test strip traces includes partially formed test strips wherein each test strip contains in the conductive layer, one or more conductive components electrically isolated from one or more of the other conductive components and one or more conductive components not electrically isolated from one or more conductive components.

21. The test card of claim 19, wherein the plurality of test strip traces includes one or more test strip traces configured laterally.

22. The test card of claim 19, wherein the plurality of test strip traces includes one or more test strip traces configured longitudinally.

23. The test card of claim 19, wherein the plurality of test strip traces includes test strip traces configured proximal end to proximal end.

24. The test card of claim 19, wherein the plurality of test strip traces includes test strips traces configured distal end to distal end.

25. The test card of claim 19, wherein the plurality of test strip traces includes test strips traces configured proximal end to distal end.

26. A method of analyzing a test card, comprising;
separating a test card comprising a plurality of partially formed test strips from a reel; and
analyzing at least one of the plurality of test strips of the test card.

27. A method of manufacturing a test card, comprising:
partially forming a plurality of attached test strips; and
separating the plurality of attached test strips card from a web.
